(19) United States
(12) Patent Application Publication
(10) Pub. No.: US 2015/0171106 A1
(43) Pub. Date: Jun. 18, 2015

(54) SEMICONDUCTOR MEMORY DEVICE AND METHOD OF MANUFACTURING THE SAME

(71) Applicant: SK hynix Inc., Icheon-si (KR)

(72) Inventor: Yong Seok SUH, Daegu (KR)

(73) Assignee: SK hynix Inc., Icheon-si (KR)

(21) Appl. No.: 14/248,693

(22) Filed: Apr. 9, 2014

(30) Foreign Application Priority Data
Dec. 17, 2013 (KR) 10-2013-0157457

(51) Int. Cl. H01L 27/115; H01L 29/161

(52) U.S. Cl. CPC H01L 27/11582; H01L 27/1157; H01L 29/161

(57) ABSTRACT

Provided are a semiconductor memory device and a method of manufacturing the same. The semiconductor memory device may include insulating patterns and conductive patterns, which are alternately stacked, a channel layer configured to pass through the insulating patterns and the conductive patterns, and a tunnel insulating layer configured to cover sidewalls of the channel layer, and the channel layer is formed of a SiGe layer in which a Ge concentration of a portion in contact with the tunnel insulating layer is greater than that of a center portion.

### CROSS-REFERENCE TO RELATED APPLICATION

The present application claims priority to Korean patent application number 10-2013-0157457 filed on Dec. 17, 2013, in the Korean Intellectual Property Office, the entire disclosure of which is incorporated by reference herein.

### TECHNICAL FIELD

The disclosure generally relates to a semiconductor device, and more particularly, to a semiconductor memory device and a method of manufacturing the same.

### BACKGROUND

Since the memory device industry such as nonvolatile memory devices is highly developed, demands for high integration of a memory device have been increasing. Typically, a degree of integration of the memory device within a certain area has increased through methods of decreasing sizes of memory cells disposed 2-dimensionally on a semiconductor substrate. However, there is a physical limit to decrease sizes of the memory cells. Because of this, disposing memory cells 3-dimensionally on a semiconductor substrate have been proposed. When the memory cells are disposed 3-dimensionally, the area of the semiconductor substrate can be efficiently used and a degree of integration thereof can be enhanced compared to the memory cells disposed 2-dimensionally. Particularly, if a 3-dimensional NAND flash memory device is implemented by disposing 3-dimensionally the memory strings of the NAND flash memory device which is useful for high integration, it is expected to maximize a degree of integration of the memory device, and thus it is required to develop the 3-dimensional semiconductor memory device.

A 3-dimensional semiconductor memory device includes word lines stacked and spaced apart from a substrate, a channel layer formed in a vertical direction of the substrate through the word lines, a tunnel insulating layer covering the channel layer, a charge storage layer covering the tunnel insulating layer, and a blocking insulating layer covering the charge storage layer. A memory cell stores data by trapping charges in a portion of the charge storage layer which is disposed at an intersection of the word lines and the channel layer.

### SUMMARY

An embodiment provides a semiconductor memory device which may include: insulating patterns and conductive patterns, which may be alternately stacked; a channel layer configured to pass through the insulating patterns and the conductive patterns; and a tunnel insulating layer that may be configured to cover sidewalls of the channel layer, and the channel layer may be formed of a SiGe layer in which a Ge concentration of a portion in contact with the tunnel insulating layer is greater than that of a center portion.

An embodiment provides a method of manufacturing a semiconductor memory device which may include: alternately stacking first material layers and second material layers; forming holes passing through the first material layers and the second material layers; and forming a tunnel insulating layer and a channel layer having a multiple structures inside each of the holes.

An embodiment may provide a method of manufacturing a semiconductor memory device which may include: alternately stacking first material layers and second material layers; forming holes passing through the first material layers and the second material layers; forming a tunnel insulating layer inside each of the holes; and sequentially stacking a first channel layer and a second channel layer on the tunnel insulating layer, such that a Ge concentration of the first channel layer may be greater than that of the second channel layer.

### BRIEF DESCRIPTION OF THE DRAWINGS

FIG. 1 is a perspective view of a semiconductor memory device according to an embodiment;

FIG. 2 is a cross-sectional view for describing a through structure by enlarging ‘A’ area shown in FIG. 1;

FIGS. 3A to 3E are cross-sectional views for describing a method of manufacturing the semiconductor memory device shown in FIG. 1;

FIG. 4 is a graph showing an increase of electron mobility according to an increase of a Ge concentration;

FIG. 5 is a graph showing a difference between currents of a channel using Ge and a channel using Si;

FIG. 6 is a block diagram showing a memory system including the semiconductor memory device shown in FIG. 1;

FIG. 7 is a block diagram showing an application example of the memory system shown in FIG. 6; and

FIG. 8 is a block diagram showing a computing system including the memory system described with reference to FIG. 7.

### DETAILED DESCRIPTION

The embodiments will be described more fully hereinafter with reference to the accompanying drawings, in which various embodiments are shown. These embodiments may, however, be embodied in different forms and should not be construed as limited to the embodiments set forth herein.

In the drawings, elements and regions are not drawn to scale and their sizes and thicknesses may be exaggerated for clarity. In the description, known configurations that are not central concepts may be omitted. Throughout the drawings and corresponding description, components are denoted by the same respective reference numerals.

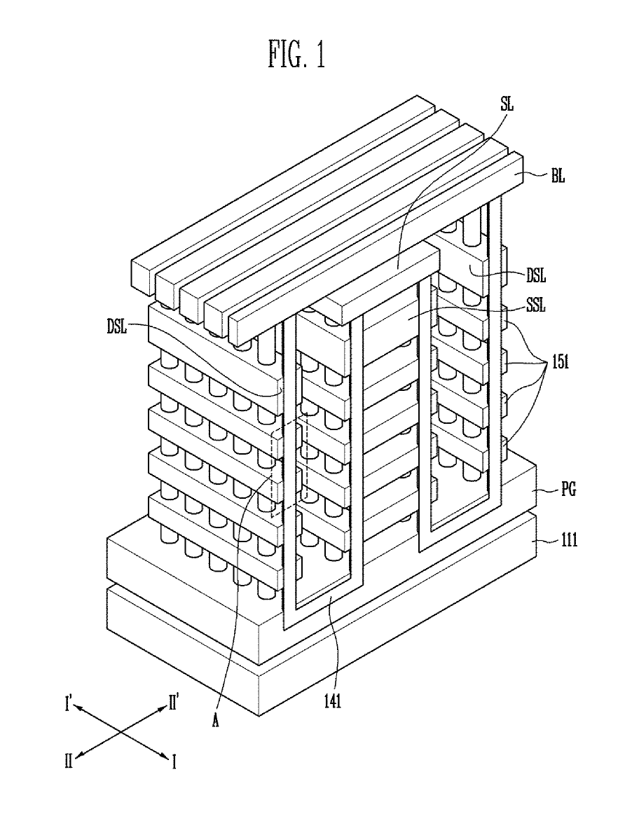

FIG. 1 is a perspective view of a semiconductor memory device according to an embodiment. In FIG. 1, an insulating layer is not shown for convenience of description.

Referring to FIG. 1, the semiconductor memory device according to an embodiment may include a pipe gate PG, a plurality of conductive patterns 151, at least one drain select line DSL, and at least one source select line SSL, which are stacked on a substrate 111, and a U-shaped through structure 141 passing through the plurality of conductive patterns 151 and the pipe gate PG.

Here, the plurality of conductive patterns 151, the drain select line DSL, and the source select line SSL are stacked to cover the through structure 141. The U-shaped through structure 141 may be coupled to bit lines BL and a source line SL.

According to the above structure, a source select transistor is formed on an intersection of the source select line SSL and the through structure 141, a memory cell is formed on an intersection of the plurality of conductive patterns 151 and the through structure 141, a pipe transistor is formed on an intersection of the pipe gate PG and the through structure 141, and a drain select transistor is formed on an intersection of the through structure 141 and the drain select line DSL.

Thus, the drain select transistor, the plurality of memory cells, the pipe transistor, the plurality of memory cells, and the source select transistor, which are connected in series, constitute one string and the strings are disposed in a U shape.

In an embodiment, a structure of which the strings are disposed in a U shape is described. However, as a common source line is formed on the substrate 111, the bit lines are formed on the common source line, and the string may be formed between the bit lines and the common source line in a straight structure, a semiconductor memory device having the string in a straight structure may be formed.

FIG. 2 is a cross-sectional view for describing a through structure by enlarging ‘A’ area shown in FIG. 1.

Referring to FIG. 2, the through structure 141 may include a channel layer 135 having a multi-structure passing through insulating patterns 121 and the conductive patterns 151, which may be alternately stacked, a tunnel insulating layer 133 covering a sidewall of the channel layer 135, and a charge storage layer 131 covering the tunnel insulating layer 133. The channel layer 135 having a multi-structure may include a first channel layer 135a and a second channel layer 135b. The first channel layer 135a and the second channel layer 135b may be formed of a SiGe layer. The first channel layer 135a may have a Ge concentration that is greater than that of the second channel layer 135b. For example, the first channel layer 135a may become a Ge-rich layer in which a molar ratio of Ge is 0.6 to 0.9. The first channel layer 135a may be formed between the tunnel insulating layer 133 and the second channel layer 135b. A center region of the channel layer 135 may be filled with an insulating layer 137. The tunnel insulating layer 133 may be formed of at least one of a thermal oxide layer, a radical oxide layer, a dry oxide layer, and a wet oxide layer. The charge storage layer 131 may be formed of a nitride layer.

In an embodiment, when the channel layer 135 is formed of a SiGe layer including Ge and Si, mobility of electrons and holes thereof may be improved compared to a semiconductor layer constituted of a polysilicon layer. The channel layer 135 may be formed in a multi-structure constituted of the first channel layer 135a and the second channel layer 135b; however, as the first channel layer 135a is formed of a Ge-rich layer having a high Ge concentration, mobility of electrons and holes of the channel layer 135 may increase and a channel current may be improved during operation of the semiconductor device.

A blocking insulating layer 147 and a barrier layer 149 may be further formed between the conductive patterns 151 and the through structure 141.

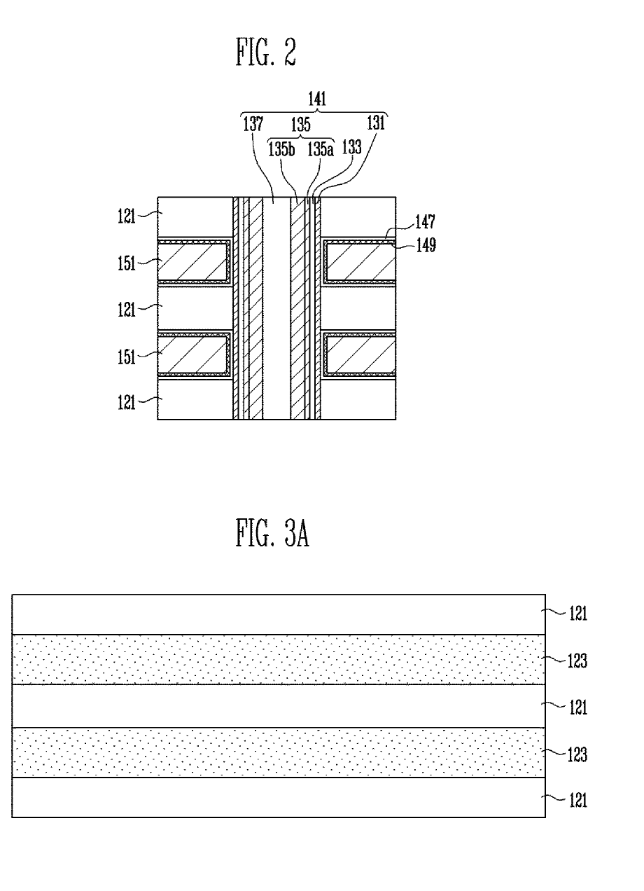

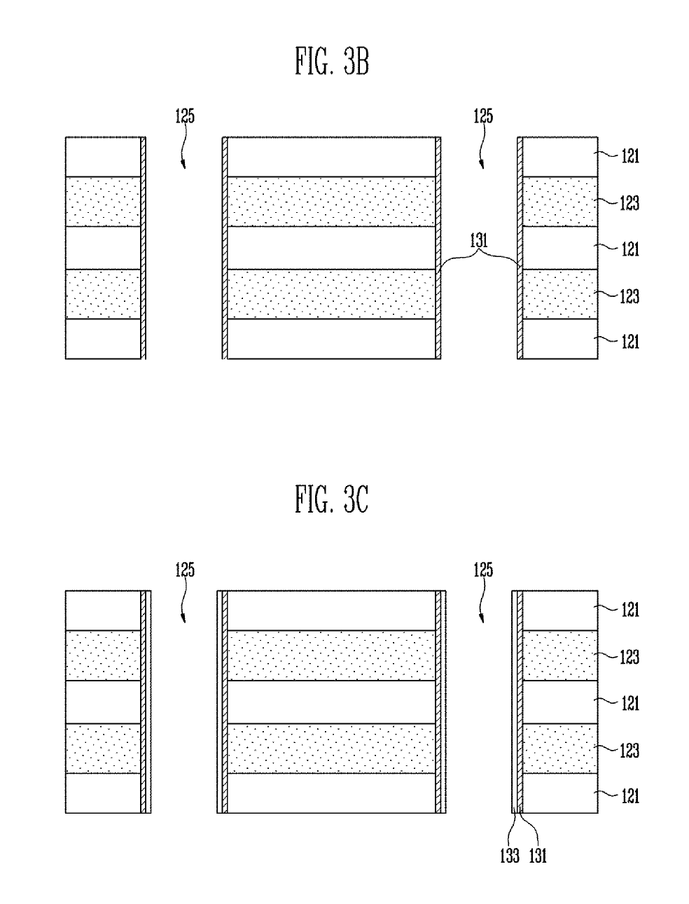

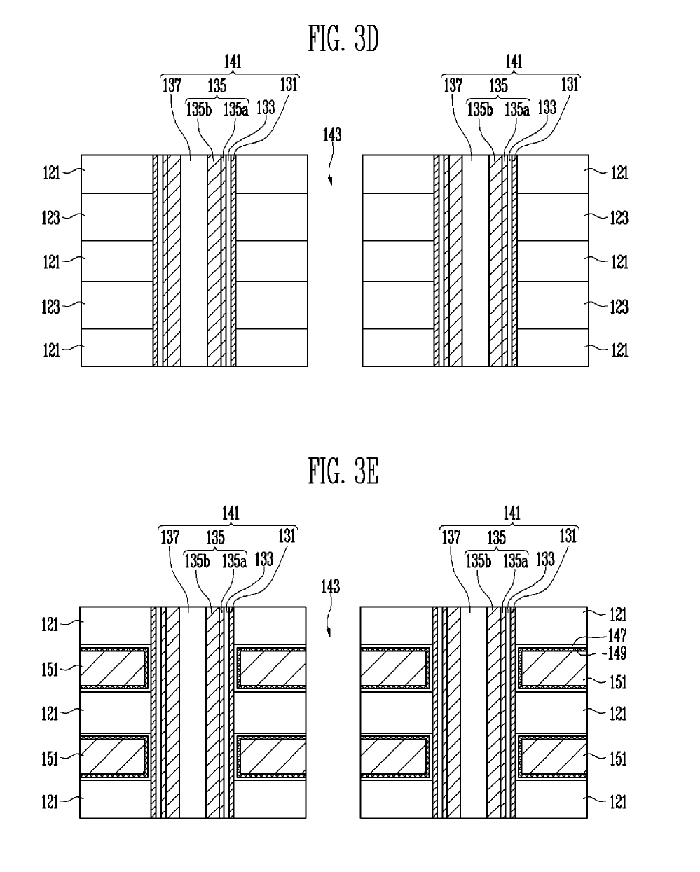

FIGS. 3A to 3E are cross-sectional views for describing a method of manufacturing the semiconductor memory devices shown in FIG. 1.

Referring to FIG. 3A, a plurality of first material layers 121 and a plurality of second material layers 123 are alternately stacked on a semiconductor substrate (not shown). The first material layers 121 and the second material layers 123 may be formed to have the same or different thickness(es).

The first material layers 121 may be formed of a material having a high etch selectivity with respect to the second material layers 123. For example, the first material layers 121 may be formed of an insulating layer such as an oxide layer and the second material layers 123 may be formed of a sacrificial layer such as a nitride layer. Alternatively, the first material layers 121 may be formed of an insulating layer such as an oxide layer and the second material layers 123 may be formed of a conductive material such as a polysilicon layer. Alternatively, the first material layers 121 may be formed of an undoped polysilicon layer and the second material layers 123 may be formed of a doped polysilicon layer.

Referring to FIG. 3B, the first material layers 121 and the second material layers 123 are etched and holes 125 passing through the first material layers 121 and the second material layers 123 are formed. Then, a charge storage layer 131 may be formed along a sidewall of each of the holes 125. The charge storage layer 131 may be formed of a nitride layer.

Referring to FIG. 3C, a tunnel insulating layer 133 may be formed on a surface of the charge storage layer 131. The tunnel insulating layer 133 may be formed of at least one of a thermal oxide layer, a radical oxide layer, a dry oxide layer, and a wet oxide layer.

Referring to FIG. 3D, a channel layer 135 may be formed on a surface of the tunnel insulating layer 133. The channel layer 135 may be formed to include a first channel layer 135a formed on the surface of the tunnel insulating layer 133 and a second channel layer 135b formed on a surface of the first channel layer 135a.

A first method of forming the first channel layer 135a and the second channel layer 135b may be as follows:

The first and second channel layers 135a and 135b may be formed by performing a heat treatment process after a SiGe layer is formed on the surface of the tunnel insulating layer 133 using a chemical vapor deposition (CVD) method. In more detail, the SiGe layer is formed on the surface of the tunnel insulating layer 133 using the CVD method in which GeH₄ and SiH₄ are used as a source gas after the tunnel insulating layer 133 is formed. Then, when the heat treatment process is performed, Si on a surface portion of the SiGe layer is combined with O of the tunnel insulating layer 133 and a SiO₂ layer is formed. Hereby, the surface portion of the SiGe layer, namely, the surface portion of the SiGe layer disposed under the SiO₂ layer has a relatively increased Ge concentration and may become a Ge-rich layer. A portion formed of a Ge-rich layer of which a Ge concentration is greater than a Si concentration among the SiGe layer is defined as the first channel layer 135a and a portion of which a Ge concentration is relatively small is defined as the second channel layer 135b.

A second method of forming the first channel layer 135a and the second channel layer 135b may be as follows:

The first channel layer 135a may be formed by performing an oxidation process after a SiGe layer is deposited on the surface of the tunnel insulating layer 133 using the CVD method. In more detail, the SiGe layer may be formed to a predefined thickness on the surface of the tunnel insulating layer 133 using the CVD method in which GeH₄ and SiH₄ are used as a source gas after the tunnel insulating layer 133 is formed. Then, as Si of the SiGe layer reacts with an oxygen gas used in the oxidation process by performing the oxidation process, the first channel layer 135a constituted of a Ge-rich layer of which a Ge concentration inside the SiGe layer is increased is formed. Then, the second channel layer 135b may be formed by depositing the SiGe layer on the surface of the first channel layer 135a using the CVD method.

The channel layer 135 may be formed to fill a center region of each of the holes 125 or may be formed in as a tube-type to have a hollow center region of each of the holes 125. When the channel layer 135 is formed in as the tube-type, the hollow center region of each of the holes 125 may be filled with an insulating layer 137.

Then, the first material layers 121 and the second material layers 123 between the holes 125 are etched and a slit 143 passing through the first material layers 121 and the second material layers 123 may be formed between the holes 125. The first material layers 121 in a line-type may be defined through the slit 143 and a side portion of the second material layers 123 may be exposed.

Referring to FIG. 3E, when the first material layers 121 are formed of an insulating layer such as an oxide layer and the second material layers 123 are formed of a sacrificial layer such as a nitride layer, recess regions are formed between the first material layers 121 by selectively removing the second material layers 123 exposed through the slit 143.

Then, conductive patterns 151 may be formed in the recess regions in which the second material layers are removed. After a conductive layer is formed to fill the inside of the recess regions, the conductive patterns 151 may be formed by removing the conductive layer formed inside the slit 143. The conductive layer may be formed using a doped polysilicon layer, a metal silicide layer, a metal layer, etc. When the conductive layer is formed using a metal layer, tungsten having a low resistance may be used. Here, a barrier layer 149 such as TiN may be further formed in order to prevent diffusion of a metal from the conductive layer before the conductive layer is formed. The barrier layer 149 formed inside the slit 143 may be removed when the conductive layer formed inside the slit 143 is removed.

A blocking insulating layer 147 may be further formed along surfaces of the recess regions before the barrier layer 149 and the conductive layer are formed in order to form the conductive patterns 151.

Then, a process may be used, such as a process where the inside of the slit 143 may be filled with an insulating material, and so on may be performed.

Though not shown in the drawings, when the first material layers 121 are formed of an insulating layer such as an oxide layer and the second material layers 123 are formed of a conductive material such as a polysilicon layer, the second material layer 123 exposed through the slit 143 becomes a silicide layer and the second material layer may be used as a conductive pattern. In these cases, the blocking insulating layer 147 is preferably formed after the holes 125 are formed and before the charge storage layer 131 is formed in the process of FIG. 3B.

Though not shown in the drawings, when the first material layers 121 are formed of an undoped polysilicon layer and the second material layers 123 are formed of a polysilicon layer, an insulating layer pattern may be formed by filling the recess regions with an insulating layer such as an oxide layer after the recess regions are formed by removing the first material layers exposed through the slit 143. The second material layers 123 may be used as a conductive pattern.

FIG. 4 is a graph showing an increase of electron mobility according to increase of a Ge concentration. Referring to FIG. 4, it may be seen that the electron mobility abruptly increases if the Ge concentration is 0.6 or more.

FIG. 5 is a graph showing a difference between currents of a channel using Ge and a channel using Si. Referring to FIG. 5, when a Ge channel is formed in a metal-oxide semiconductor field effect transistor (MOSFET), it may be seen that the current thereof increases about 3 times than that of a Si channel.

Accordingly, as in the embodiments, when the channel layer 135 is formed of a SiGe layer including Ge and Si, mobility of electrons and holes is improved compared to a semiconductor layer constituted of a polysilicon layer, and as a surface portion of the channel layer 135 in contact with the tunnel insulating layer 133 is formed of a Ge-rich layer, the mobility of electrons and holes of the channel layer 135 further increases and the channel current thereof is improved during operation of the semiconductor device.

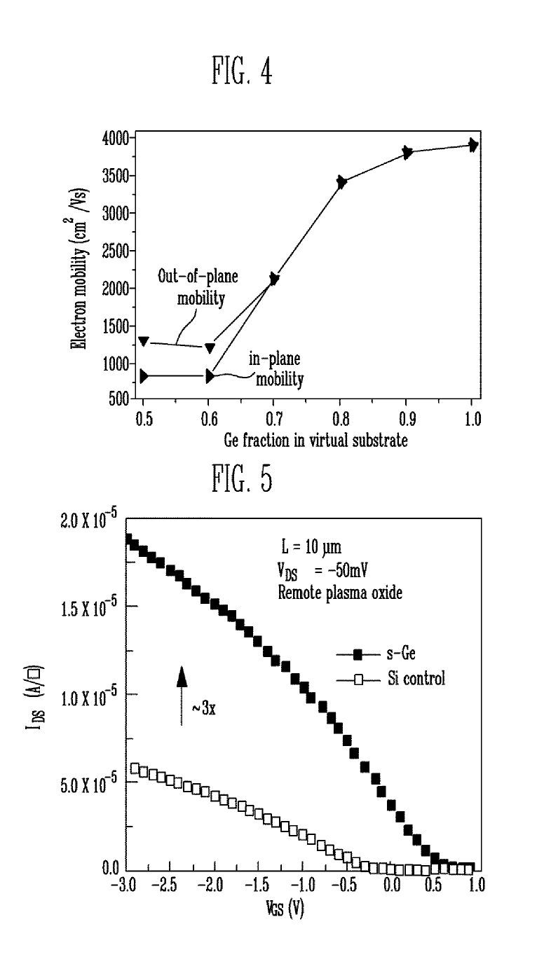

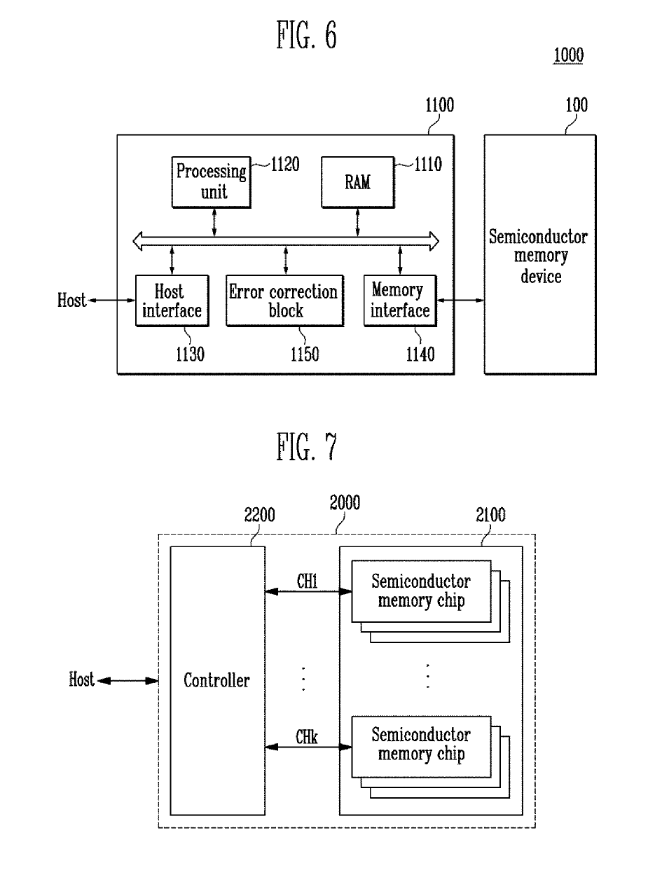

FIG. 6 is a block diagram showing a memory system including the semiconductor memory device shown in FIG. 1 and discussed with relation to FIGS. 2-5.

Referring to FIG. 6, a memory system 1000 may include a semiconductor memory device 100 and a controller 1100.

The semiconductor memory device 100 is configured to include the semiconductor device described with reference to FIG. 1 and may operate as described above. Hereinafter, the description thereof will not be repeated.

The controller 1100 may be coupled to a host Host and the semiconductor memory device 100. The controller 1100 may be configured to access the semiconductor memory device 100 in response to a request from the host Host. For example, the controller 1100 may be configured to control read, write, erase, and background operations of the semiconductor memory device 100. The controller 1100 may be configured to provide an interface between the semiconductor memory device 100 and the host Host. The controller 1100 may be configured to drive firmware in order to control the semiconductor memory device 100.

The controller 1100 may include a random access memory (RAM) 1110, a processing unit 1120, a host interface 1130, a memory interface 1140, and an error correction block 1150. The RAM 1110 may be used as at least one of an operation memory of the processing unit 1120, a cache memory between the semiconductor memory device 100 and the host Host, and a buffer memory between the semiconductor memory device 100 and the host Host. The processing unit 1120 may control an overall operation of the controller 1100. Also, the controller 1100 may store temporarily program data provided from the host Host when a write operation is performed.

The host interface 1130 may include a protocol to exchange data between the host Host and the controller 1100. In an embodiment, the controller 1100 may be configured to communicate with the host Host through at least one of various interface protocols such as a Universal Serial Bus (USB) protocol, a MultiMediaCard (MMC) protocol, a Peripheral Component Interconnection (PCI) protocol, a PCI-Express (PCI-E) protocol, an Advanced Technology Attachment (ATA) protocol, a Serial-ATA protocol, a Parallel-ATA protocol, a Small Computer System Interface (SCSI) protocol, an Enhanced Small Disk Interface (ESDI) protocol, an Integrated Drive Electronics (IDE) protocol, a private protocol, and so on.

The memory interface 1140 interfaces with the semiconductor memory device 100. For example, the memory interface 1140 may include a NAND interface and a NOR interface.

The error correction block 1150 may be configured to detect and correct an error of data received from the semiconductor memory device 100 using an error correcting code (ECC). The processing unit 1120 may adjust a read voltage according to an error detection result of the error correction block 1150 and control the semiconductor memory device 100 in order to perform re-read. In an embodiment, the error correction block 1150 may be provided as a component of the controller 1100.

The controller 1100 and the semiconductor memory device 100 may be integrated into one semiconductor device. In an embodiment, the controller 1100 and the semiconductor memory device 100 may be integrated into one semiconductor device and configure a memory card. For example, the controller 1100 and the semiconductor memory device 100 may be integrated into one semiconductor device and may configure a memory card such as a personal computer (PC) card (Personal Computer Memory Card International Association (PCMCIA)), a Compact Flash (CF) card, a SmartMedia (SM) card (SMC), a Memory Stick, an MMC (reduced Size MMC (RS-MMC), MMCmicro), a Secure Digital (SD) card (miniSD, microSD, SD High Capacity (SDHC)), a Universal Flash Storage (UFS), and so on.

The controller 1100 and the semiconductor memory device 100 may be integrated into one semiconductor device and may configure a solid state drive (SSD). The SSD may include a storage device configured to store data in a semiconductor memory. When the memory system 1000 is used as the SSD, an operation speed of the host Host connected to the memory system 1000 may be innovatively enhanced.

In an embodiment, the memory system 1000 may be provided as at least one of various components of an electronic device such as a computer, an ultra mobile PC (UMPC), a workstation, a netbook, a personal digital assistant (PDA), a portable computer, a web tablet, a wireless phone, a mobile phone, a smartphone, an e-book, a portable multimedia player (PMP), a portable game console, a navigation device, a black box, a digital camera, a 3-dimensional television, a digital audio recorder, a digital audio player, a digital picture recorder, a digital picture player, a digital video recorder, a digital video player, a device for wirelessly sending and receiving information, at least one of various electronic devices configuring a home network, at least one of various electronic devices configuring a computer network, at least one of various electronic devices configuring a telematics network, an RFID device, at least one of various components configuring a computing system, etc.

In an embodiment, the semiconductor memory device 100 or the memory system 1000 may be mounted in various forms of packages. For example, the semiconductor memory device 100 or the memory system 1000 may be packaged in such a manner such as a Package on Package (PoP), Ball grid arrays (BGAs), Chip scale packages (CSPs), a Plastic Leaded Chip Carrier (PLCC), a Plastic Dual In Line Package (PDIP), a Die in Waffle Pack, a Die in Wafer Form, a Chip On Board (COB), a Ceramic Dual In Line Package (CERDIP), a Plastic Metric Quad Flat Pack (MQFP), a Thin Quad Flatpack (TQFP), a Small Outline (SOIC), a Shrink Small Outline Package (SSOP), a Thin Small Outline (TSOP), a Thin Quad Flatpack (TQFP), a System In Package (SIP), a Multi Chip Package (MCP), a Wafer-level Fabricated Package (WFP), a Wafer-Level Processed Stack Package (WSP), and so on, and may be mounted.

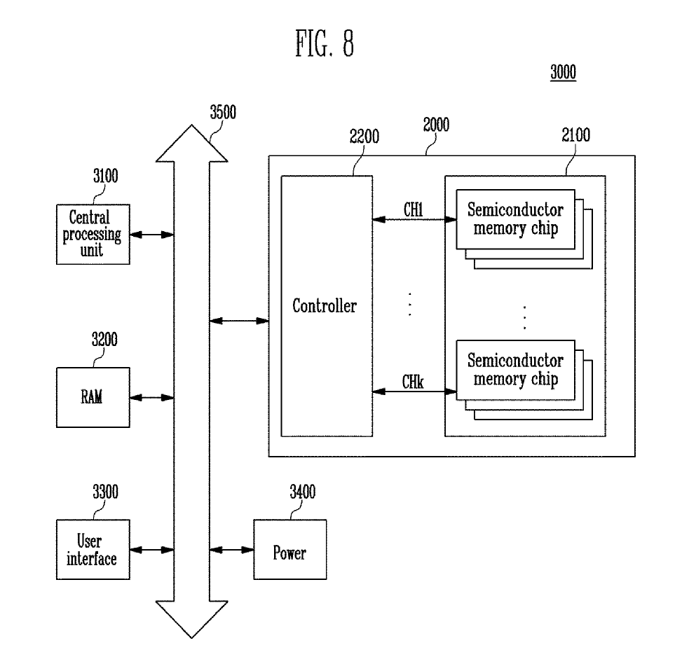

FIG. 7 is a block diagram showing an application example of the memory system shown in FIG. 6.

Referring to FIG. 7, a memory system 2000 may include a semiconductor memory device 2100 and a controller 2200. The semiconductor memory device 2100 includes a plurality of semiconductor memory chips. The plurality of semiconductor memory chips are divided as a plurality of groups.

In FIG. 7, the plurality of groups are shown to communicate with the controller 2200 through first to kth channels CH1 to CHk, respectively. Each semiconductor memory chip may be configured and operate as the semiconductor memory device 100 of FIG. 6 described with reference to FIG. 1 and discussed with relation to FIGS. 2-5.

Each group may be configured to communicate with the controller 2200 through one common channel. The controller 2200 may be configured as the controller 1100 described with reference to FIG. 6 and configured to control the plurality of semiconductor memory chips of the semiconductor memory device 2100 through the plurality of channels CH1 to CHk.

FIG. 8 is a block diagram showing a computing system including the memory system described with reference to FIG. 7.

Referring to FIG. 8, a computing system 3000 may include a central processing unit 3100, a random access memory (RAM) 3200, a user interface 3300, power 3400, a system bus 3500, and the memory system 2000.

The memory system 2000 may be electrically coupled to the central processing unit 3100, the RAM 3200, the user interface 3300, and the power 3400 through the system bus 3500. Data which is provided through the user interface 3300 or processed by the central processing unit 3100 may be stored in the memory system 2000.

In FIG. 8, the semiconductor memory device 2100 is shown to couple to the system bus 3500 through the controller 2200. However, the semiconductor memory device 2100 may be configured to connect directly to the system bus 3500. Here, a function of the controller 2200 may be performed by the central processing unit 3100 and the RAM 3200.

In FIG. 8, the memory system 2000 described with reference to FIG. 7 is shown and provided. However, the memory system 2000 may be replaced with the memory system 1000 described with reference to FIG. 6. In an embodiment, the computing system 3000 may include all of the memory systems 1000 and 2000 described with reference to FIGS. 6 and 7.

According to the embodiments, as a channel layer of the 3-dimensional semiconductor memory device is formed of a material of which moving speed of an electron and hole is faster than that of polysilicon, a channel current thereof may be increased.

Various embodiments have been described. However, various modifications may be made without departing from the scope and spirit of these embodiments. Therefore, the scope of the invention is not defined by the detailed description of the invention but by the appended claims and equivalents within the scope of the appended claims.

In the drawings and specification, there have been disclosed various examples of embodiments, and although specific terms are employed, they are used in a generic and descriptive sense only and not for purposes of limitation. As for the scope of the embodiments, it is to be set forth in the following claims. Therefore, it will be understood by those of ordinary skill in the art that various changes in form and details may be made therein without departing from the spirit and scope of the embodiments as defined by the following claims.

What is claimed is:

1. A semiconductor memory device, comprising:
insulating patterns and conductive patterns, which are alternately stacked;
a channel layer configured to pass through the insulating patterns and the conductive patterns; and
a tunnel insulating layer configured to cover sidewalls of the channel layer,
wherein the channel layer is formed of a SiGe layer in which a Ge concentration of a portion in contact with the tunnel insulating layer is greater than that of a center portion.

2. The semiconductor memory device of claim 1, wherein the channel layer is formed of a multi-structure layer.

3. The semiconductor memory device of claim 1, wherein the channel layer comprises:
a first channel layer in contact with the tunnel insulating layer; and
a second channel layer in contact with the first channel layer.

4. The semiconductor memory device of claim 3, wherein the first channel layer is a Ge-rich SiGe layer and the second channel layer is a SiGe layer.

5. The semiconductor memory device of claim 3, wherein a Ge concentration of the first channel layer is greater than that of the second channel layer.

6. The semiconductor memory device of claim 3, further comprising a SiO₂ layer interposed between the first channel layer and the tunnel insulating layer.

7. The semiconductor memory device of claim 3, wherein a molar ratio of Ge concentration of the first channel layer is 0.6 to 0.9.

8. A method of manufacturing a semiconductor memory device, comprising:
alternately stacking first material layers and second material layers;
forming holes passing through the first material layers and the second material layers; and
forming a tunnel insulating layer and a channel layer having a multiple structure inside each of the holes.

9. The method of claim 8, wherein the forming of the channel layer having a multiple structure comprises:
forming a SiGe layer on a surface of the tunnel insulating layer; and
forming a first channel layer and a second channel layer sequentially stacked on the surface of the tunnel insulating layer by performing a heat treatment process.

10. The method of claim 9, wherein a Ge concentration of the first channel layer is greater than that of the second channel layer.

11. The method of claim 9, wherein the SiGe layer is formed using a chemical vapor deposition method using GeH₄ and SiH₄.

12. The method of claim 9, wherein Si in the SiGe layer is combined with O of the tunnel insulating layer and the SiGe layer becomes a Ge-rich layer using the heat treatment process.

13. The method of claim 12, wherein a molar ratio of Ge concentration of the Ge-rich layer is 0.6 to 0.9.

14. The method of claim 9, wherein the first channel layer includes a SiGe layer and a SiO₂ layer.

15. A method of manufacturing a semiconductor memory device, comprising:
alternately stacking first material layers and second material layers;
forming holes passing through the first material layers and the second material layers;
forming a tunnel insulating layer inside each of the holes; and
sequentially stacking a first channel layer and a second channel layer on the tunnel insulating layer, such that a Ge concentration of the first channel layer is greater than that of the second channel layer.

16. The method of claim 15, wherein the forming of the first channel layer and the second channel layer comprises:
forming the first channel layer by performing an oxidation process after forming a SiGe layer on a surface of the tunnel insulating layer; and
forming the second channel layer by depositing the SiGe layer on the first channel layer.

17. The method of claim 16, wherein the SiGe layer is formed using a chemical vapor deposition method using GeH₄ and SiH₄.

18. The method of claim 16, wherein a SiO₂ layer is formed on a surface of the first channel layer using the oxidation process, and
a Ge concentration of the first channel layer disposed under the SiO₂ layer increases.

19. The method of claim 15, wherein a molar ratio of Ge concentration of the first channel layer is 0.6 to 0.9.

20. The method of claim 15, wherein the first channel layer includes a SiGe layer and a SiO₂ layer.
